(19) United States
(12) Patent Application Publication
(10) Pub. No.: US 2025/0277830 A1
(43) Pub. Date: Sep. 4, 2025

(54) SYSTEM AND METHOD FOR CONFIGURING METERING DEVICES WITH OUTOF- THE-BOX FUNCTIONALITY VIA A BATCH CONFIGURATION TOOL

(71) Applicant: Accuenergy (Canada) Inc., Toronto (CA)

(72) Inventors: Yufan Wang, Toronto (CA); Ketao Li, Toronto (CA); Liang Wang, Toronto (CA)

(73) Assignee: Accuenergy (Canada) Inc., Toronto (CA)

(21) Appl. No.: 18/593,984

(22) Filed: Mar. 4, 2024

(51) Int. Cl. G01R 21/133; H04L 67/12

(52) U.S. Cl. CPC G01R 21/1333; H04L 67/12

(57) ABSTRACT

The present disclosure relates to a system and method for configuring metering devices with out-of-the-box functionality via a batch configuration tool, designed to streamline the configuration of power meters and communication devices within a networked environment. The system leverages a sophisticated batch configuration tool installed on a computing device, enabling the simultaneous configuration of multiple metering devices. This tool facilitates the rapid deployment of these devices by pre-configuring them with predefined operational parameters, including settings necessary for measuring electrical power consumption and facilitating data transmission, The interconnection of these metering devices through a network with a computing device allows for efficient, centralized management and deployment, ensuring that the devices are ready for immediate operational use. This invention addresses the need for a more efficient, reliable, and user-friendly approach to pre-configure metering devices before deployment.

### FIELD OF THE INVENTION

The present disclosure generally relates to the field of energy management systems and, particularly to a system and method for configuring metering devices with out-of-the-box functionality via a batch configuration tool.

### BACKGROUND

Energy management is a critical concern for modern industrial and commercial facilities, aiming to optimize energy consumption, reduce operational costs, and minimize environmental impact. The advent of smart metering devices has significantly advanced these goals by enabling precise measurement and real-time monitoring of electrical power usage. However, the setup, configuration, and integration of these devices into existing networks and systems pose substantial challenges.

Traditionally, metering devices require manual configuration by technicians, a process that can be time-consuming, prone to errors, and inefficient, especially when dealing with large numbers of devices. Additionally, the evolving need for remote and cloud-based energy data analysis has necessitated the development of systems that can securely and efficiently manage the data collected from these devices.

The integration of metering devices with cloud-based platforms, such as AWS or Azure, offers the potential for advanced data analytics, predictive maintenance, and optimized energy management. However, achieving this integration smoothly and securely, especially in systems that include a variety of device types and configurations, remains a technical challenge.

Thus, there is a need for an innovative system and method that simplifies the configuration of metering devices before deployment,

### SUMMARY OF THE INVENTION

The present invention pertains to an advanced metering device configuration system and method designed to optimize the configuration of metering devices within a networked environment.

According to some embodiments, a metering device configuration system is provided comprising a plurality of metering devices, including power meters and communication devices, configured to measure electrical power consumption and facilitate data transmission, respectively; a network facilitating interconnection among the metering devices and a computing device; a batch configuration tool installed on the computing device, designed to perform simultaneous configuration of the metering devices through the network, wherein the batch configuration tool is configured to pre-configure the metering devices for immediate operational use upon deployment by setting predefined parameters.

According to some embodiments, the system further comprises a cloud-based energy management system accessible via the network, configured for the aggregation and analysis of data, and wherein the batch configuration tool is further configured to enable cloud access for the metering devices, facilitating the transmission of operational data directly to the cloud-based energy management system for enhanced data management and analytical processing.

According to some embodiments, the network is Ethernet network, RS485 network, or Modbus network.

According to some embodiments, the predefined parameters include IP addresses, data collection intervals, and communication protocols.

According to some embodiments, the batch configuration tool employs a multicast DNS (mDNS) protocol to discover the metering devices on the network, facilitating the identification of the metering devices by broadcasting an mDNS query and populating a device list based on responses from the metering devices.

According to some embodiments, the batch configuration tool further comprises a user interface (UI) displayed on the computing device, enabling a user to configure the metering devices by selecting said devices through a selection box displayed within the UI and utilizing function buttons within the UI to download, upload, delete configuration files, update firmware, and manage remote and cloud access settings.

According to some embodiments, the UI further enables testing of cloud access for the metering devices by sending a predefined data packet to the cloud-based energy management system to verify the communication link and confirm the registration status of the metering devices.

According to some embodiments, the configuration files are in JSON (JavaScript Object Notation) format, enabling structured and easily interpretable data exchange for device configuration.

According to some embodiments, the batch configuration tool and the metering devices employs a secure key exchange protocol that utilizes polymorphic keys, ensuring the confidentiality of the metering devices scanning process.

According to some embodiments, the secure key exchange protocol includes the use of a pre-shared secret and a session identifier generated from the current timestamp and a nonce to establish a unique identifier for each session, enhancing the security of the initial communication phase between the batch configuration tool and the metering devices.

According to some embodiments, the polymorphic keys, used for encrypting and decrypting communications within the session, is generated by incorporating device-specific login credentials including username and password into the key generation process, further securing the communication channel established with each metering device.

According to some embodiments, the batch configuration tool is configured to perform a verification process by sending an encrypted verification message to the metering devices, and upon receiving an encrypted acknowledgment, decrypts and verifies the acknowledgment using the polymorphic key to confirm the successful authentication and secure channel establishment.

According to some embodiments, the encrypted verification message and the acknowledgment include a predefined pattern or token known to both the batch configuration tool and the metering device, facilitating mutual authentication and ensuring the integrity of the established secure communication channel.

According to some embodiments, a method for configuring metering devices within a network is provided, the method comprising interconnecting a plurality of metering devices, including power meters and communication devices, with a cloud-based energy management system and a computing device through a network; utilizing a batch configuration tool installed on the computing device for simultaneous configuration of the metering devices by setting predefined parameters for immediate operational use upon deployment and enabling cloud access for the metering devices to facilitate the transmission of operational data directly to the cloud-based energy management system for data aggregation and analysis.

According to some embodiments, the network comprises one of an Ethernet network, an RS485 network, or a Modbus network, and wherein setting predefined parameters includes configuring IP addresses, data collection intervals, and communication protocols for the metering devices.

According to some embodiments, the method further comprising employing a multicast DNS (mDNS) protocol with the batch configuration tool to discover the metering devices on the network by broadcasting an mDNS query and creating a device list based on responses from said metering devices.

According to some embodiments, the method further comprising displaying a user interface (UI) on the computing device by the batch configuration tool, which enables a user to select metering devices for configuration via a selection box and utilize function buttons to download, upload, delete configuration files, update firmware, and manage remote and cloud access settings.

According to some embodiments, the configuration files are in JSON (JavaScript Object Notation) format to facilitate structured and interpretable data exchange for device configuration.

According to some embodiments, the method further comprising employing a secure key exchange protocol that utilizes polymorphic keys, ensuring the confidentiality of the metering devices scanning process.

According to some embodiments, wherein the secure key exchange protocol includes the use of a pre-shared secret and a session identifier generated from the current timestamp and a nonce to establish a unique identifier for each session, enhancing the security of the initial communication phase between the batch configuration tool and the metering devices.

This invention introduces a comprehensive system and method for the expedited and efficient configuration of metering devices within a networked environment. It represents a significant advancement in the field of metering device management, offering substantial benefits in terms of operational efficiency.

### BRIEF DESCRIPTION OF THE DRAWINGS

The forgoing and other advantages of the present disclosure will become apparent upon reading the following detailed description and upon reference to the drawing.

FIG. 1 a diagram of the metering device configuration system, illustrating the interconnection of power meters and communication devices through an Ethernet network to a PC equipped with a specialized batch configuration tool for pre-deployment device setup according to some embodiments of the present invention.

FIG. 2 is a diagram of the scanning user interface integral to the batch configuration tool, designed to facilitate the efficient identification and configuration of networked devices within an Ethernet network, according to some embodiments of the present invention.

FIG. 3 is a flow chart of the scanning process, showcasing the sequential steps executed by the batch configuration tool for each device within the Ethernet network, according to some embodiments of the present invention.

FIG. 4 is a flow chart illustrating a secure authentication mechanism designed to verify the identity of each metering device within an Ethernet network employing a detailed secure key exchange protocol that utilizes polymorphic keys, according to some embodiments of the present invention.

FIG. 5 is a diagram of an exemplary user interface designed for the configuration of metering devices following the scanning process, according to some embodiments of the present invention.

FIG. 6 is a diagram of an exemplary user interface designed for configuring cloud access capabilities of metering devices, according to some embodiments of the present invention.

FIG. 7 is a diagram of an exemplary JSON format configuration file, designed to customize and optimize the operation of a power meter, according to some embodiments of the present invention.

### DETAILED DESCRIPTION

The following description should be read with reference to the drawings, in which like elements in different drawings are numbered in like fashion. The drawings, which are not necessarily to scale, depict selected embodiments and are not intended to limit the scope of the invention. Although examples of construction, dimension, and materials are illustrated for the various elements, those skilled in the art will recognize that many of the examples provided have suitable alternatives that may be utilized.

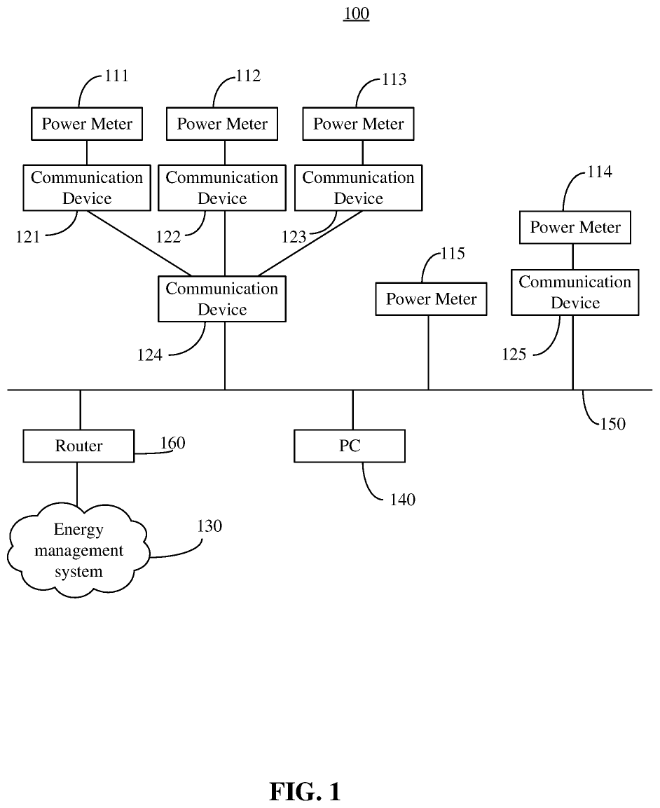

FIG. 1 illustrates an exemplary metering device configuration system 100, designed to enhance the setup process for metering devices, including both power meters 111-115 and communication devices 121-125, prior to their deployment. The system includes multiple power meters 111-115 and communication devices 121-125, interconnected through an Ethernet network 150 to a PC 140 equipped with a specialized batch configuration tool.

The essence of the batch configuration tool is its ability to facilitate the simultaneous configuration of numerous metering devices, a feature that significantly enhances efficiency and accuracy in system setup. By enabling mass configuration, this tool eliminates the time-consuming and often error-prone process of individually setting up each device.

Functioning through an Ethernet network 150, the batch configuration tool ensures that each power meter and communication device is correctly and consistently configured according to predefined parameters.

Moreover, the tool's design incorporates a user-friendly interface, allowing technicians and system administrators to easily select configurations for an entire network of devices without the need for specialized programming knowledge. Whether it's setting IP addresses, configuring data collection intervals, or establishing communication protocols, the batch configuration tool provides a comprehensive and accessible solution for preparing metering devices for immediate operational use upon deployment.

The metering devices central to this invention encompass both power meters 111-115 and communication devices 121-125. The power meters are engineered to accurately measure electrical power consumption in various circuits, while the communication devices enable efficient data transmission between the power meters and other components. These components include but not limited to the cloud-based energy management system 130, communication devices and power meters.

A component of the system 100 is the cloud-based energy management system 130, which grants users expansive access to data harvested from the metering devices. Hosted on renowned cloud platforms such as AWS or Azure, this system utilizes advanced analytics to offer valuable insights into energy consumption patterns, facilitating efficient energy management.

The system includes a PC 140 armed with a batch configuration tool, a pivotal element for manufacturers. This tool permits the pre-configuration of the metering devices (both power meters and communication devices), imbuing them with the necessary functionality for “out-of-the-box” operation. This pre-configuration process is vital, as it eliminates the need for end-users to engage in complex setup procedures, thereby significantly reducing deployment time and technical challenges.

Router 160 serves as the network gateway that bridges the Ethernet network, comprising power meters and communication devices, with the cloud-based energy management system 130, which is hosted on platforms such as AWS or Azure, external to the Ethernet infrastructure. In an embodiment, the cloud-based energy management system 130 is exemplified by Accuenergy's AcuCloud.

In an embodiment, communication device 124 is identified as Accuenergy's AcuLink 810, this device serves as an intelligent server and gateway, designed specifically for the aggregation of energy data collected from multiple metering devices. Its primary function is to facilitate the centralized collection and forwarding of energy usage data, enabling efficient data management and analysis.

In an embodiment, communication device 125 is exemplified by Accuenergy's AXM-WEB2 module, a device that significantly enhances the communication capabilities of metering systems. It is equipped with an expanded memory capacity of 8GB and includes integrated WiFi and dual Ethernet ports. These features ensure compatibility with a broad spectrum of industrial and commercial protocols, including Ethernet/IP, thus guaranteeing its seamless integration into diverse operational environments.

In an embodiment, power meter 115 is represented by Accuenergy's AcuRev 2100, this multi-circuit submeter is recognized for its precision in energy measurement. Engineered to monitor energy consumption across multiple circuits, it is instrumental in providing detailed energy usage insights, thereby facilitating optimized energy management strategies.

In an embodiment, power meter 114 is designated as Accuenergy's Acuvim L, this multifunction meter is praised for its ease of integration into various project environments. It supports a wide array of plug-in expansion modules, which enable communication across over 15 different industry-standard protocols, demonstrating its versatility and adaptability to specific project requirements.

In an embodiment, power meters 111-113 are identified as Accuenergy's AcuRev 1310, a series of DIN Rail meters engineered for high performance and ease of integration into both industrial and commercial facilities. Their design emphasizes reliability and accuracy in energy data measurement, supporting effective energy monitoring and management.

In an embodiment, communication devices 121-123 are portrayed as Accuenergy's wireless transceiver AcuMesh, these devices enable wireless data transmission between the power meters and the central communication device. Their inclusion in the system underscores the commitment to flexibility and ease of installation, particularly in environments where wired connections may be impractical or cost-prohibitive.

The embodiment depicted in FIG. 1, illustrating the metering device configuration system 100 interconnected through an Ethernet network 150, serves as a prime example of the system's network interface capabilities. However, it is important to emphasize that the choice of an Ethernet network in this illustration is purely exemplary and not limiting. The metering device configuration system 100 is designed to be compatible with a wide range of network protocols and infrastructures,

Accordingly, the system 100 is fully capable of operating over alternative network frameworks such as RS485 networks or Modbus networks, among others. RS485 networks, known for their robustness in industrial environments and ability to support long-distance communication, present a viable option for environments where serial communication is preferred or where network infrastructure necessitates high noise immunity and reliable data transmission over greater distances.

Similarly, Modbus networks, whether implemented over serial lines (Modbus RTU/ASCII) or Ethernet (Modbus TCP), are also compatible with the system 100. Modbus, with its wide acceptance in industrial automation and control systems, allows for seamless integration of the metering device configuration system within environments that already utilize Modbus for device communication and control.

This adaptable approach to network connectivity underscores the innovation and versatility of the metering device configuration system, making it a comprehensive solution for the setup of metering devices in diverse operational environments.

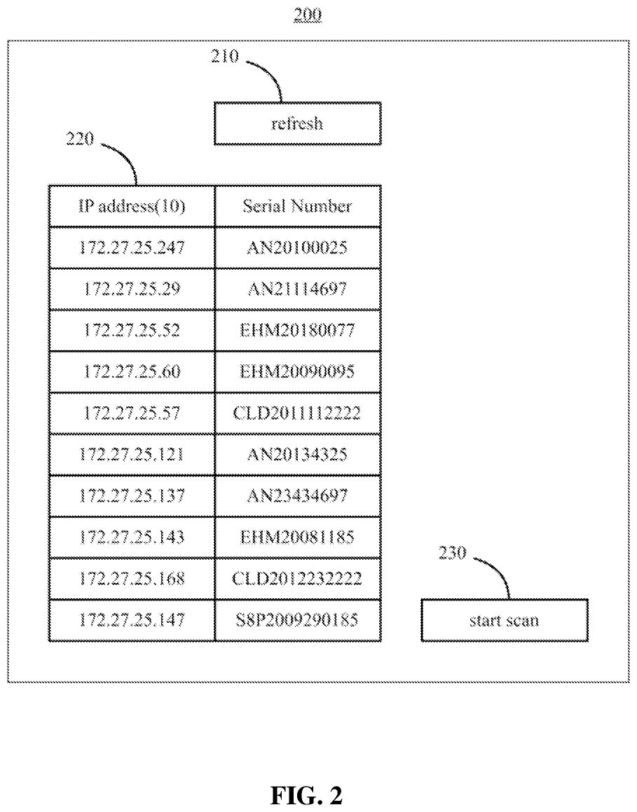

FIG. 2 presents a comprehensive diagram of the scanning user interface 200 integral to the batch configuration tool, designed to facilitate the efficient identification and configuration of networked devices within an Ethernet network 150. This interface is pivotal in enabling technicians to initiate and manage the scanning process for detecting devices, including both power meters and communication devices as depicted in FIG. 1.

Device List 220 is a structured display area listing detected devices by IP address and serial number. It is designed to accommodate information for devices corresponding to the power meters and communication devices identified in the network, as shown in FIG. 1. Each entry in the device list 220 is organized to present the IP address in the left column and the serial number in the right column, facilitating easy identification.

Refresh button 210 is a functional control that enables the technician to initiate a new scan of the Ethernet network 150 by sending a multicast message. This feature is essential when new devices are added to the network, ensuring that the device list 220 remains up-to-date with all networked devices.

Upon the activation of the scanning user interface 200, the batch configuration tool broadcasts the mDNS query and listens for responses from mDNS-capable devices. Each response is parsed to extract essential information, including the device's IP address, serial number, and any additional identifiers provided in the TXT records. This information is used to populate and continuously update the device list 220. The tool employs error handling mechanisms to address non-responsive devices and validation checks to ensure data integrity. An automated update mechanism refreshes the device list in real-time as new devices join or leave the network.

Discovered device information is then populated in the device list 220, with each device's IP address and serial number displayed. The notation “(10)” adjacent to an IP address signifies the total number of devices detected on the network, providing the technician with a quick overview of the network's composition.

While the described embodiment focuses on Ethernet networks, the invention is adaptable to other network types, such as Wi-Fi, RS485, or Modbus networks, by modifying the mDNS query broadcasting mechanism to suit the specific network protocol. This adaptability ensures the invention's applicability across a wide range of network environments and device types.

The refresh button 210 plays a crucial role in maintaining the accuracy and completeness of the device list 220. By re-initiating the mDNS discovery process, it ensures that any newly added devices are detected and listed, thereby supporting dynamic network environments where devices may be frequently added or removed.

Following the preliminary device detection, the start-scan button 230 facilitates a more in-depth interaction with each detected device. This advanced scanning phase enables the batch configuration tool to retrieve detailed device information, which may include firmware versions, configuration statuses, and other pertinent operational data. This capability is essential for technicians to assess the readiness of each device in the system and to perform any necessary configurations or updates.

When activated, start-scan button 230 triggers the batch configuration tool to engage in a deeper communication with the detected devices, aiming to gather more comprehensive information beyond just IP addresses and serial numbers. This step is crucial for configuring specific device settings and verifying operational status.

The scanning user interface 200 of the batch configuration tool, as illustrated in FIG. 2, represents a mechanism for the discovery and initial configuration of networked devices using the mDNS protocol. Through its intuitive design and the strategic implementation of mDNS, it streamlines the process of integrating and configuring power meters and communication devices within Ethernet networks.

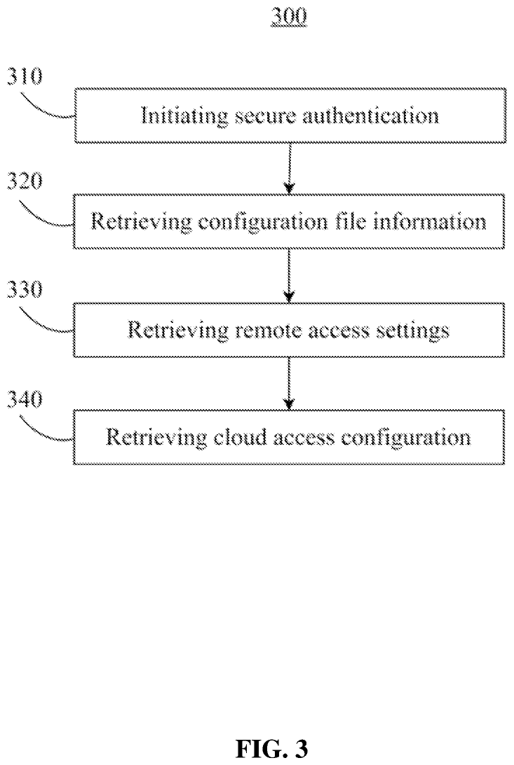

FIG. 3 delineates a flow chart of the scanning process after users press the start-scan button 230, detailing the sequential steps executed by the batch configuration tool for each device within the Ethernet network 150. This process is designed to authenticate, retrieve, and manage critical device information, facilitating optimal device performance and remote accessibility.

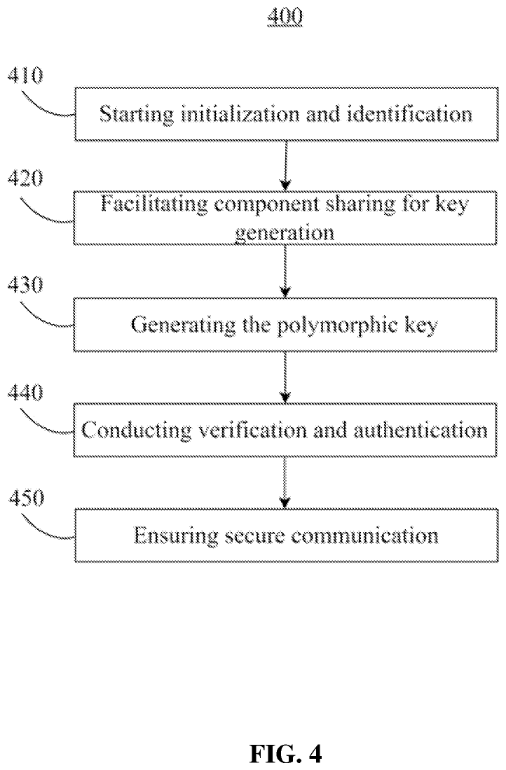

In step 310, the process begins with the batch configuration tool initiating communication with devices identified within the Ethernet network 150, utilizing the IP addresses listed in device list 220. This initiation step employs a secure authentication mechanism to verify the identity of each device, further details of which are elaborated in FIG. 4.

In step 320, the batch configuration tool queries and retrieves the device's configuration file information, which includes critical details such as the configuration file's version and timestamp. This step is essential for maintaining the device's software up-to-date and ensuring compatibility with the latest network protocols and security standards.

In step 330, the batch configuration tool queries and retrieves the device's remote access settings, determining whether the feature is activated or deactivated. Remote access allows devices to be managed and configured remotely via a secure connection, typically through an HTTPS web server. This capability is crucial for devices deployed in locations that are physically inaccessible to network administrators, enabling them to perform administrative tasks, configurations, and troubleshooting remotely.

In step 340, the batch configuration tool queries and retrieves the device's cloud access configuration, identifying whether this functionality is enabled. Cloud access refers to the device's ability to send operational data to a cloud-based energy management system, allowing for real-time data monitoring, analysis, and storage. This feature is instrumental for integrating devices into broader IoT ecosystems, where data can be aggregated, analyzed, and used for optimizing energy consumption, predictive maintenance, and other advanced analytical applications.

FIG. 4 illustrates a secure authentication mechanism designed to verify the identity of each metering device within an Ethernet network 150, employing a detailed secure key exchange protocol that utilizes polymorphic keys. This mechanism is pivotal in ensuring the confidentiality and integrity of the authentication process, facilitating the generation of session-specific encryption keys without the direct transmission of these keys.

In step 410, each device connected to the Ethernet network 150 is recognized by its serial number and equipped with a pre-shared secret (PSS), laying the groundwork for secure communication. Upon initiating a session, the batch configuration tool generates a session identifier (SessionID). This SessionID is created from the current timestamp and a nonce, guaranteeing a unique identifier for each session.

In step 420, the batch configuration tool takes the lead by generating a random number (R1) and amalgamating it with its SessionID to formulate a component (C1). This component is encrypted using the pre-shared secret and dispatched to the device, accompanied by the device's serial number. Upon receipt, the device decrypts C1 utilizing the PSS to extract RI and the SessionID. Subsequently, the device generates its random number (R2), merges it with the received SessionID to create a component (C2), encrypts this using the PSS, and sends it back to the tool along with the device's serial number.

In step 430, upon the tool's receipt of C2, it decrypts the component to recover R2 and confirms the SessionID's match. The tool utilizes R1, R2, the SessionID, and the serial number of the device, along with a crucial addition-the username and password designated for accessing the device's configuration webpage. These login credentials, unique to each device, are securely stored within the tool and are retrievable via the device's serial number. By integrating these credentials into the key generation process, the tool calculates the session-specific polymorphic key using a predetermined hash function. This method not only incorporates an additional security layer by leveraging the device-specific login credentials but also personalizes the encryption key for each session. Consequently, the device independently derives the identical polymorphic key utilizing the same set of inputs. This synchronized computation ensures the establishment of a symmetric key for the session, significantly enhancing the security framework for device authentication and secure communication.

In step 440, to affirm the successful key exchange and generation, the batch configuration tool encrypts a verification message with the newly formulated polymorphic key, sending it to the device for decryption. The device decrypts the message using its polymorphic key. Successful decryption and verification of the message, identified by a predefined pattern or token known to both parties, prompt the device to dispatch an encrypted acknowledgment back to the tool, signifying the completion of the authentication phase. The tool decrypts the received acknowledgment using the polymorphic key. It then examines the decrypted message for the expected response pattern or token, verifying the device's successful decryption and acknowledgment of the initial verification message. Finding the correct response pattern or token within the decrypted acknowledgment confirms the mutual authentication between the device and the tool. This step is critical as it ensures that both the batch configuration tool and the device have correctly generated and agreed upon the use of the polymorphic key, validating the secure communication channel established between them.

In step 450, with the authentication process complete and the polymorphic key validated, the tool and the device utilize this key for encrypting and decrypting all communications within the session. This secure communication channel is critical for the protected exchange of sensitive data, such as device configurations and firmware updates.

The secure authentication mechanism depicted in FIG. 4, leveraging a secure key exchange protocol with polymorphic keys, establishes a fortified framework for verifying device identities and securing communications within an Ethernet network. This innovative approach, prioritizing session-specific encryption keys and dynamic key management, substantially elevates the security posture of the device configuration process, ensuring robust protection against unauthorized access and data breaches.

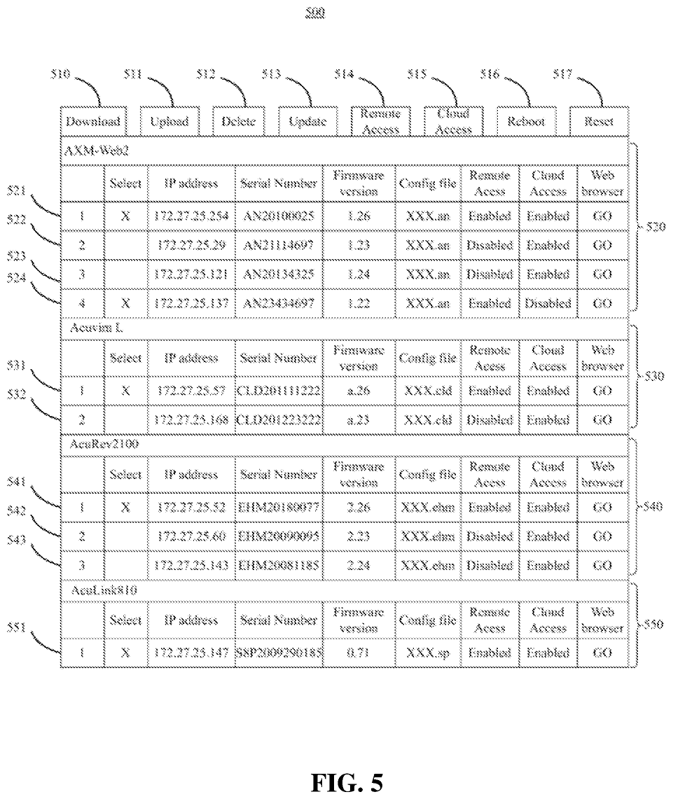

FIG. 5 introduces a user interface (UI) 500, specifically designed for the configuration of metering devices following the scanning process outlined in FIG. 3. This interface is meticulously crafted to display configuration information for various types of metering devices, facilitating a streamlined and efficient configuration process.

In the UI 500, devices of identical models are grouped together to enhance usability and navigation. For example, the AXM-Web2 modules 521-524 are prominently displayed within table 520. This methodical grouping ensures that products of the same type are easily accessible, allowing users to apply uniform configuration settings where applicable.

The table 520 is structured to provide comprehensive details about each metering device, organized into several informative columns:

1. Ordinal Number: The first column numerically lists each AXM-Web2 module for easy reference.

2. Selection Box: The second column features a selection box for each device. By selecting this box, users can specify which metering devices they wish to configure, enabling batch configurations or individual device settings adjustments,

3. IP Address: Displayed in the third column, it provides the network address for each device, critical for network configuration and connectivity tests.

4. Serial Number: The fourth column lists the serial number of each device, offering a unique identifier for inventory and tracking purposes.

5. Firmware Version: The fifth column indicates the firmware version installed on the device, essential for ensuring devices operate with the latest features and security updates.

6. Configuration File: Shown in the sixth column, this specifies the current configuration file used by the device, allowing users to review or modify device settings as needed.

7. Remote Access Settings: The seventh column reveals whether remote access is enabled (‘Enabled’) or disabled (‘Disabled’), signifying whether the device can be managed remotely through a secure connection.

8. Cloud Access Configuration: The eighth column indicates if the device is configured to send operational data to a cloud-based energy management system, with ‘Enabled’ meaning active data transmission capabilities, and ‘Disabled’ indicating no cloud connectivity.

9. Web Browser Configuration Button: The ninth column features a button that, when pressed, launches a web browser. This opens a configuration webpage based on the device's IP address, allowing for intuitive, web-based device setup.

Similarly, the user interface 500 incorporates additional tables for various device models, including Acuvim L (531-532) displayed in table 530, AcuRev2100 (541-543) in table 540, and AcuLink810 (551) in table 550. Each table follows the same structured format as table 520, ensuring consistency across device types and facilitating a unified configuration approach.

In FIG. 5, the user interface (UI) 500 also introduces a mechanism for configuring metering devices, facilitated through an intuitive selection process across tables 520, 530, 540, and 550. Following the selection of a device via the select box associated with each table, users are empowered to perform a variety of configuration tasks utilizing function buttons 510-517, each designed to execute specific actions for the enhancement and management of device settings.

1. Download Button 510: Upon the user's activation of the download button, the configuration file currently employed by the selected metering device is securely transferred and saved to PC 140. This function initiates a request to the device for its current configuration file, which, upon authorization, is encrypted and sent over the network to ensure data integrity and security during transmission.

2. Upload Button 511: Engaging the upload button allows users to select a configuration file stored on PC 140, which is then uploaded to the selected metering device. This process involves the encryption of the configuration file and its secure transmission to the device, where it is decrypted and applied, effectively updating the device's operational parameters.

3. Delete Button 512: By pressing the delete button, users can remove the configuration file from the selected metering device. This action sends a secure command to the device instructing the deletion of its current configuration file, a process that requires confirmation to prevent unintended data loss.

4. Update Button 513: The update button facilitates the upgrading of firmware within the selected metering device. This involves selecting a firmware update file on PC 140, which is then encrypted and transmitted to the device. Upon receipt, the device decrypts the firmware, verifies its integrity and compatibility, and proceeds with the update, ensuring the device operates with the latest features and security enhancements.

5. Remote Access Button 514: Activation of the remote access button toggles the remote access functionality of the selected metering device. This button sends a command to enable or disable the device's ability to be accessed and configured remotely via a secure connection, enhancing flexibility in device management.

6. Cloud Access Button 515: Through the cloud access button, users can enable or disable the device's capability to send operational data to a cloud-based energy management system.

7. Reboot Button 516: The reboot button permits users to remotely restart the selected metering device. This action is particularly useful for applying new configurations or updates, where a reboot is necessary for changes to take effect. The command issued ensures a safe reboot process, minimizing disruption to device operation.

8. Reset Button 517: Engaging the reset button allows users to restore the selected metering device to its factory settings. This critical function is safeguarded by a confirmation step to prevent accidental data loss, ensuring that it is intentionally executed by the user.

Each button function is supported by a backend process that securely communicates with the selected device over the network. Implementing these functionalities involves establishing a secure session between PC 140 and the device, using encryption and secure authentication methods to protect the commands and data exchanged. The UI is designed to provide feedback to the user regarding the success or failure of each action, incorporating error handling and logging to aid in troubleshooting and ensuring a smooth configuration experience.

The UI 500, as detailed in FIG. 5, represents a comprehensive tool for the efficient configuration and management of metering devices, offering users a range of functionalities from firmware updates to remote management capabilities. By integrating secure communication protocols and user-friendly interface design, this system significantly enhances the operability and security of metering devices within the network.

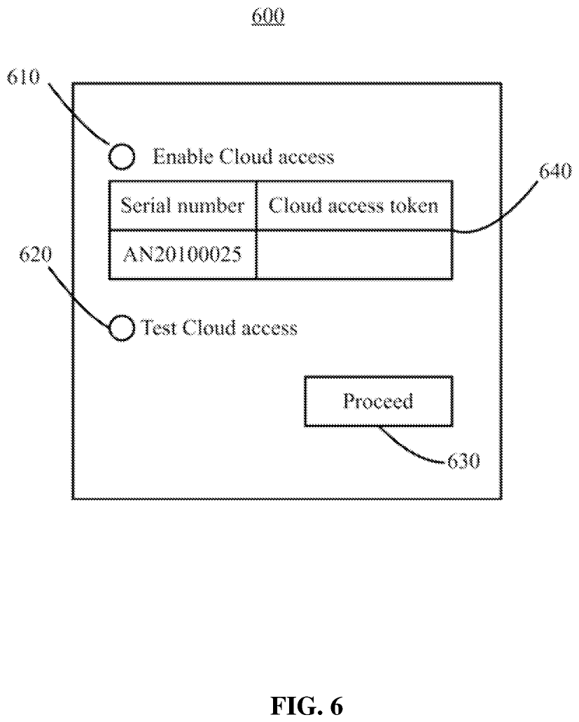

FIG. 6 unveils a user interface (UI) 600, crafted for configuring cloud access capabilities of metering devices, activated subsequent to the user's interaction with button 515 in FIG. 5. This UI is meticulously designed to streamline the process of enabling and testing cloud access for selected metering device, ensuring seamless integration with cloud-based energy management systems.

Upon launching UI 600, the user is presented with two primary options, facilitated through radio buttons 610 and 620, for enabling cloud access and conducting cloud access tests, respectively.

### 1. Enabling Cloud Access (Radio Button 610):

Selection of radio button 610 initiates the procedure to activate cloud access for the chosen metering device. Below this option, table 640 is displayed, featuring two critical columns:

The first column showcases the serial number of the selected metering device, providing a unique identifier for cloud registration purposes.

The second column contains an editable field where users input the cloud access token specific to the metering device. This token, essential for secure cloud communication, is acquired from the cloud-based energy management system 130.

With the cloud access token entered, users finalize the enabling process by pressing button 630. This action triggers the transmission of the device's serial number and the entered cloud access token to the cloud-based energy management system 130 for validation.

The cloud-based energy management system 130 then verifies the submitted serial number and token against its records. Successful validation registers the device, allowing it to transmit operational data to the cloud-based system 130 henceforth.

### 2. Testing Cloud Access (Radio Button 620):

Following successful cloud access configuration, radio button 620 empowers users to verify the operational efficacy of the cloud connection. By selecting this option and engaging button 630, the UI initiates a diagnostic test to ascertain the robustness of the cloud access.

Upon the user's activation of radio button 620 and engagement with button 630, the test sequence commences. The first segment of the test involves the metering device sending a predefined data packet to the cloud-based energy management system 130. This packet is crafted to simulate typical operational data, enabling a realistic assessment of the data transmission pathway.

Upon receipt, the cloud-based energy management system 130 acknowledges the data packet and conducts an integrity check. This step is pivotal in evaluating the communication link's reliability, ensuring that data transmitted by the device is received intact and without corruption.

Concurrently, the cloud-based energy management system 130 performs a crucial verification process to confirm the metering device's registration status. The outcome of both test segments—communication link integrity and registration status—is then relayed back to the user via UI 600. Positive confirmation of data integrity and device registration is indicated through success notifications, while any issues encountered during the test trigger error messages, guiding the user towards troubleshooting steps or reconfiguration advice.

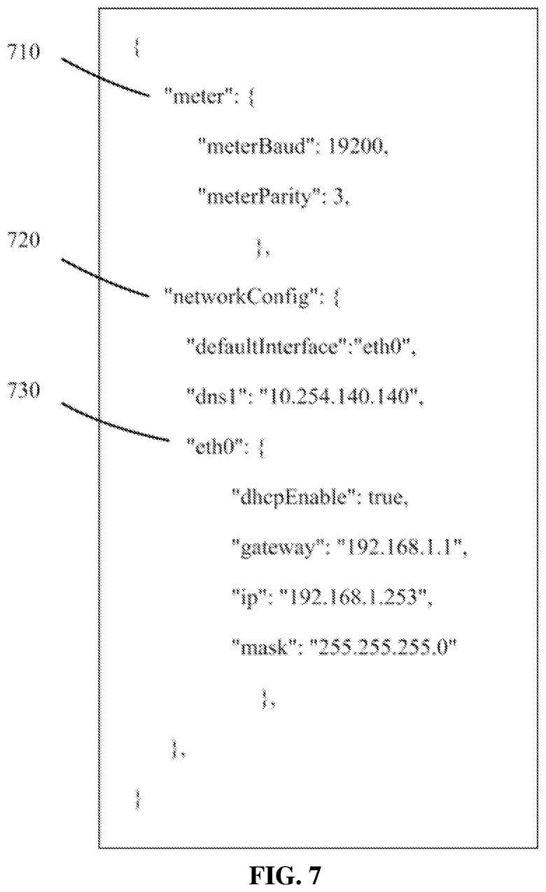

FIG. 7 provides a comprehensive view of a JSON (JavaScript Object Notation) format configuration file 700, meticulously designed to customize and optimize the operation of a power meter. This configuration file enables precise and automated setup of the power meter's communication protocols, network interfaces, and operational parameters, ensuring the device functions efficiently within its network environment.

The configuration file defines the communication settings of the power meter 710, setting a baud rate of 19200 to facilitate swift and reliable data transmission. The parity is meticulously configured to a value of ‘3’, enhancing the integrity of the communication by allowing for error checking and correction. This careful calibration ensures that the power meter can maintain dependable communication links under various operational conditions, crucial for accurate energy measurement and data reporting.

The network configuration 720 is articulated with precision, specifying ‘eth0’ as the primary network interface to anchor the power meter to its digital communication landscape. This section includes configurations for DNS servers, integral to the power meter's ability to resolve network addresses and maintain seamless connectivity with external systems, such as cloud-based energy management platforms.

In an in-depth configuration of the ‘eth0’ interface 730, the configuration file explicitly disables the Dynamic Host Configuration Protocol (DHCP), opting instead for a static IP configuration. This strategic choice assigns the power meter a permanent IP address of ‘192.168.1.254’, accompanied by a subnet mask of ‘255.255.255.0’, effectively segmenting the network and enhancing security. The gateway for outbound network traffic is designated as ‘192.168.1.1’, ensuring that the power meter can communicate beyond its local network when necessary.

Upon downloading this configuration file to the power meter, the device parses the JSON structure and applies the settings automatically. This process transforms the raw data into actionable configurations, adjusting the power meter's internal settings to align with the specified parameters. The use of JSON not only facilitates a structured and organized presentation of configuration options but also supports interoperability and ease of modifications, accommodating future updates or changes in network requirements.

The JSON configuration file 700, as depicted in FIG. 7, represents a sophisticated approach to configuring power meters, ensuring they are finely tuned for optimal performance and connectivity. Through this advanced configuration mechanism, power meters can achieve precise operational standards, contributing to the overall efficiency and reliability of energy management systems.

While the foregoing descriptions illustrate the present invention in the context of a three-phase power meter, it should be recognized that the principles and teachings of the invention are equally applicable to multi-channel power meters. Those of ordinary skill in the art will appreciate that the inventive concepts disclosed herein can be adapted for use in power meters capable of monitoring multiple channels, thereby extending the utility and application of the invention beyond the specific example of a three-phase power meter.

Embodiments of the teachings of the present disclosure have been described in an illustrative manner. It is to be understood that the terminology that has been used, is intended to be in the nature of words of description rather than of limitation. Many modifications and variations of the embodiments are possible in light of the above teachings. Therefore, within the scope of the appended claims, the embodiments can be practiced other than specifically described.

What is claimed is:

1. A metering device configuration system comprising:
a plurality of metering devices, including power meters and communication devices, configured to measure electrical power consumption and facilitate data transmission, respectively;
a network facilitating interconnection among the metering devices and a computing device;
a batch configuration tool installed on the computing device, designed to perform simultaneous configuration of the metering devices through the network, wherein the batch configuration tool is configured to pre-configure the metering devices for immediate operational use upon deployment by setting predefined parameters.

2. The system of claim 1, wherein the system further comprises a cloud-based energy management system accessible via the network, configured for the aggregation and analysis of data, and wherein the batch configuration tool is further configured to enable cloud access for the metering devices, facilitating the transmission of operational data directly to the cloud-based energy management system for enhanced data management and analytical processing.

3. The system of claim 1, wherein the network is Ethernet network, RS485 network, or Modbus network.

4. The system of claim 1, wherein the predefined parameters include IP addresses, data collection intervals, and communication protocols.

5. The system of claim 1, wherein the batch configuration tool employs a multicast DNS (mDNS) protocol to discover the metering devices on the network, facilitating the identification of the metering devices by broadcasting an mDNS query and populating a device list based on responses from the metering devices.

6. The system of claim 1, wherein the batch configuration tool further comprises a user interface (UI) displayed on the computing device, enabling a user to configure the metering devices by selecting said devices through a selection box displayed within the UI and utilizing function buttons within the UI to download, upload, delete configuration files, update firmware, and manage remote and cloud access settings.

7. The system of claim 6, wherein the UI further enables testing of cloud access for the metering devices by sending a predefined data packet to the cloud-based energy management system to verify the communication link and confirm the registration status of the metering devices.

8. The system of claim 6, wherein the configuration files are in JSON (JavaScript Object Notation) format, enabling structured and easily interpretable data exchange for device configuration.

9. The system of claim 1, wherein the batch configuration tool and the metering devices employs a secure key exchange protocol that utilizes polymorphic keys, ensuring the confidentiality of the metering devices scanning process.

10. The system of claim 9, wherein the secure key exchange protocol includes the use of a pre-shared secret and a session identifier generated from the current timestamp and a nonce to establish a unique identifier for each session, enhancing the security of the initial communication phase between the batch configuration tool and the metering devices.

11. The system of claim 10, wherein the polymorphic keys, used for encrypting and decrypting communications within the session, is generated by incorporating device-specific login credentials including username and password into the key generation process, further securing the communication channel established with each metering device.

12. The system of claim 11, wherein the batch configuration tool is configured to perform a verification process by sending an encrypted verification message to the metering devices, and upon receiving an encrypted acknowledgment, decrypts and verifies the acknowledgment using the polymorphic key to confirm the successful authentication and secure channel establishment.

13. The system of claim 12, wherein the encrypted verification message and the acknowledgment include a predefined pattern or token known to both the batch configuration tool and the metering device, facilitating mutual authentication and ensuring the integrity of the established secure communication channel.

14. A method for configuring metering devices within a network, the method comprising:
interconnecting a plurality of metering devices, including power meters and communication devices, with a cloud-based energy management system and a computing device through a network;
utilizing a batch configuration tool installed on the computing device for simultaneous configuration of the metering devices by setting predefined parameters for immediate operational use upon deployment and enabling cloud access for the metering devices to facilitate the transmission of operational data directly to the cloud-based energy management system for data aggregation and analysis.

15. The method of claim 14, wherein the network comprises one of an Ethernet network, an RS485 network, or a Modbus network, and wherein setting predefined parameters includes configuring IP addresses, data collection intervals, and communication protocols for the metering devices.

16. The method of claim 14, further comprising employing a multicast DNS (mDNS) protocol with the batch configuration tool to discover the metering devices on the network by broadcasting an mDNS query and creating a device list based on responses from said metering devices.

17. The method of claim 14, further comprising displaying a user interface (UI) on the computing device by the batch configuration tool, which enables a user to select metering devices for configuration via a selection box and utilize function buttons to download, upload, delete configuration files, update firmware, and manage remote and cloud access settings.

18. The method of claim 17, wherein the configuration files are in JSON (JavaScript Object Notation) format to facilitate structured and interpretable data exchange for device configuration.

19. The method of claim 14, further comprising employing a secure key exchange protocol that utilizes polymorphic keys, ensuring the confidentiality of the metering devices scanning process.

20. The method of claim 19, wherein the secure key exchange protocol includes the use of a pre-shared secret and a session identifier generated from the current timestamp and a nonce to establish a unique identifier for each session, enhancing the security of the initial communication phase between the batch configuration tool and the metering devices.
